(19) United States
(12) Patent Application Publication
(10) Pub. No.: US 2014/0145710 A1
(43) Pub. Date: May 29, 2014

(54) SYSTEM FOR CALIBRATING AND MEASURING MECHANICAL STRESS IN AT LEAST A PART OF A RAIL

(71) Applicant: Herman Roelof Noback, Groningen (NL)

(72) Inventor: Herman Roelof Noback, Groningen (NL)

(73) Assignee: GRONTMIJ NEDERLAND B.V., De Bilt (NL)

(21) Appl. No.: 14/005,095

(22) PCT Filed: Mar. 13, 2012
(86) PCT No.: PCT/NL2012/050153

§ 371 Date: Dec. 23, 2013

Related U.S. Application Data
(60) Provisional application No. 61/452,698, filed on Mar. 15, 2011.

(30) Foreign Application Priority Data
Mar. 15, 2011 (NL) 2006395

(51) Int. Cl. G01R 35/00; G01L 1/12

(52) U.S. Cl. CPC G01R 35/007; G01L 1/127
USPC 324/202; 324/234

(57) ABSTRACT

The invention relates to a system for calibrating and measuring the magnetizability of at least a part of a rail, for instance a rail for guiding means of transport. The system includes a magnetic field generator for generating a changing magnetic field transverse to a longitudinal direction of the rail. The magnetic field generator comprises a substantially saddle-shaped transmitter coil arranged to be placed partly around the rail. The system further includes an induction detector for measuring a transverse induction. The system may further include a magnetic field generator for generating a changing magnetic field in the longitudinal direction, an induction detector arranged for measuring a longitudinal induction, and a processing unit arranged for determining a reference induction, on the basis of the transverse induction, and determining a longitudinal mechanical stress in rail on the basis of the longitudinal induction and the reference induction.

The invention relates to a system and a method for at least detecting a mechanical stress in at least a part of a rail, for instance a rail for guiding means of transport.

The above-mentioned system and the above-mentioned method are known per se. A train which experiences the effects of stress in a rail, such as deformation of the rail, when the train moves forward over this rail, can be understood as an example of an above-mentioned system and an above-mentioned method. Such effects may, for instance, comprise an increased resistance experienced by the train when it moves forward over the rail. The method usually also comprises the visual detection of deformation of the rail as a result of the presence of a mechanical stress in at least a part of the rail.

Currently, nearly always jointless tracks are used. That is, there are no interruptions in the rails of the track. A result is that particularly temperature changes and the driving of, for instance, trains cause a tensile stress or compressive stress in the rail.

Forces developing in the rail can cause “rail buckling”. This is a phenomenon which occurs when a longitudinal force in the rail is so great that a ballast bed connected with the rail, and/or the fixation to, for instance, the cross ties and/or the rail's own shear resistance cannot prevent the rail from reaching its buckling point. The buckling point is the point at which a virtually straight object can no longer remain straight due to the pressure exerted thereon in longitudinal direction, but will bend (buckle). The buckling usually takes place suddenly, and rail buckling is an example thereof. The magnitude of the force needed to make a rail buckle depends, for instance, on how straight a rail lies, how much lateral resistance the ballast bed can offer, and the amount of cross ties connected with the rail per unit of length of the rail.

The system, the method using visual inspection of the rails and the phenomenon of “rail buckling” as described hereinabove signal the occurrence of mechanical stresses at much too late a stage of the phenomena occurring as a result of mechanical stresses.

International patent application WO 2006/080838, of the present applicant, proposes a system and a method for detecting mechanical stresses in at least a part of a rail at an early stage, so that the rail can be replaced if desired, or can be adjusted otherwise before buckling of the rail takes place. Said system and method allow for measuring a global stress in a longitudinal direction of a rail. Here, measuring local stresses and/or local stress variations in the rail may be of secondary importance. The rail generally is a magnetizable metal rail such as a steel rail.

The magnetizability of the respective part of a rail is a property which can be determined without the respective part of the rail needing to be moved, and without any mechanical stresses which are present in the respective part of the rail being substantially influenced. The invention follows from the insight that the so-called Villari effect will occur in rails. In short, in this context, this effect comprises that the magnetizability of a rail, as observed through Villari, is influenced by mechanical stresses which are present in the rail.

Therefore, said system is arranged for at least detecting a mechanical stress in at least a part of a rail, for instance a rail for guiding means of transport, on the basis of magnetizability of the respective part of a rail, wherein the system is provided with a magnetic field generator for generating at least one predetermined changing magnetic field such that the respective part of a rail is located in that field, and is provided with a measuring system for measuring a response of the respective part of a rail to its being located in that magnetic field. The magnetic field generator may comprise at least one electrically conductive turn arranged to be able to be placed at least partly around the rail.

In this context, a magnetic field extending in a determined direction is understood to mean that magnetic field lines extend more or less parallel to that determined direction.

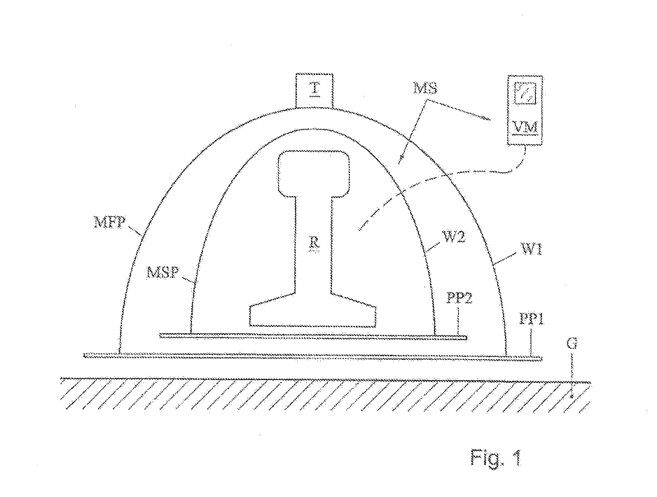

For calibration of said system, WO 2006/080838 proposed that the system may be provided with at least one magnetizable reference object with a predetermined magnetizability. This allows a relative determination of mechanical stresses in the respective part of the rail. This is because the relative magnetic induction, the induction in the respective part of the rail in relation to the induction in the reference object, can be determined. The measuring system may comprise a reference measuring coil for determining the magnetic induction in the reference object. Optionally, providing this reference measuring coil may also be combined with providing the turn of the magnetic field generator and providing the measuring coil which determines the magnetic induction in the respective part of the rail. Alternatively, the embodiment of FIG. 1 of WO 2006/080838 could be provided with a measuring system arranged for measuring the magnetic induction in the direction transverse to the longitudinal direction of the respective part of the rail, and optionally with a second magnetic field generator, which generates a magnetic field extending in a direction transverse to the longitudinal direction of the respective part of the rail. It had been found that, since the magnetizability of the rail in the direction transverse to the longitudinal direction of the respective part of the rail does not or hardly change and/or changes differently from the magnetizability in the longitudinal direction of the respective part of the rail as a result of mechanical stresses in the longitudinal direction of the respective part of the rail, the magnetic induction in the direction transverse to the longitudinal direction of the respective part of the rail could be used as a reference value (calibration value) for a stressless situation in the respective part of the rail. Thus, no separate reference object would be necessary.

It is an object of the present invention to further improve upon the above calibration methods, and to provide a calibration device and measurement system arranged for use therein.

Thereto, according to the invention is provided a calibration system for measuring the magnetizability of at least a part of a rail, for instance a rail for guiding means of transport, the system being arranged for, in use, having a longitudinal direction thereof aligned with a longitudinal direction of at least the part of the rail. The system is provided with a magnetic field generator for generating at least one predetermined changing magnetic field in a direction transverse to a longitudinal direction of the calibration system. That is, in use the generated magnetic field will be transverse to the longitudinal direction of at least the part of the rail. The magnetic field generator comprises a substantially saddle-shaped transmitter coil arranged to, in use, be placed partly around the rail and to extend, in use, substantially in the longitudinal direction of the rail on either side of the rail. The system is further provided with a magnetic induction detector arranged for measuring a magnetic induction oriented in the direction transverse to the longitudinal direction of the calibration system. That is, in use the magnetic induction detector will detect a magnetic induction in the direction transverse to the longitudinal direction of at least the part of the rail. In use, the detected magnetic induction will be a response of the respective part of the rail to its being located in the generated magnetic field. A length of the transmitter coil in the longitudinal direction of the calibration system is at least four times larger than a dimension of the substantially saddle-shaped coil measured in a direction substantially orthogonal to the longitudinal direction of the calibration system.

The substantially saddle-shaped transmitter coil provides the advantage that the coil can be placed over the rail without needing to loop around the rail. The substantially saddle-shaped transmitter coil comprises a first incomplete electrically conductive turn, arranged to be placed partly around the rail, and a second incomplete electrically conductive turn, arranged to be placed partly around the rail. The first and/or second incomplete turns may be substantially U-shaped so as to be placed partly around the rail. The first and/or second incomplete turn may extend in a plane that includes at least one direction orthogonal to the longitudinal direction. Preferably, each of the first and second incomplete turns each in its own plane that is substantially orthogonal to the longitudinal direction. The first and the second incomplete turn are mutually electrically conductively connected by a first and/or second longitudinal part extending, in use, substantially in the longitudinal direction of the calibration system, on either side of the rail.

The first and/or second longitudinal parts of the transmitting coil generate magnetic field components in a direction orthogonal to the longitudinal direction of the rail. These magnetic field components are usable for determining the transverse magnetizability of the rail in the direction transverse to the longitudinal direction of the rail. This transverse magnetizability is representative of the rail without mechanical stress. The first and second incomplete electrically conductive turns generate magnetic field components in the longitudinal direction of the rail. These magnetic field components are usable for determining the longitudinal magnetizability of the rail in the longitudinal direction of the rail. This longitudinal magnetizability is representative of mechanical stress in at least the part of the rail. However, the inventors have found that the longitudinal magnetic field components generated by the first and second incomplete electrically conductive turns may disturb the measurement of the transverse magnetizability. This potentially could cause a calibration of the stressless situation of the rail to yield erroneous results. Alternatively, or additionally, this could potentially render setting up the calibration device for proper calibration cumbersome in view of potentially disturbing elements such as fixing means that fix the rail to the sleepers.

The inventors realized that, nevertheless, the substantially saddle-shaped transmitting coil may be conveniently used for accurately determining the transverse magnetizability if the length of the transmitter coil in the longitudinal direction of the rail is at least four times larger than the dimension of first and/or second incomplete turn measured in a direction substantially orthogonal to the rail. Then, the substantially saddle-shaped transmitter coil provides the magnetic field such that at the center the magnetic field is substantially uniquely transverse to the longitudinal direction of the rail. The longitudinal magnetic field components generated near the incomplete turns are then far enough spaced away from the center of the transmitter coil not to negatively influence the ability to determine the transverse magnetizability.

The inventors also realized that with such transmitter coil it is possible to determine both the transverse magnetizability with a detector near the center of the transmitter coil and the longitudinal magnetizability with a further detector near the first and/or second incomplete turn. This will be elucidated more in detail below.

Preferably, the magnetic induction detector has a dimension in the longitudinal direction of the calibration system that is at least five times smaller than the length of the transmitter coil. This provides that the magnetic induction detector can be positioned, and extend, at the position where the magnetic field generated by the substantially saddle-shaped transmitter coil is substantially transverse to the longitudinal direction of the rail. Preferably, the magnetic induction detector is positioned at or near the center of the transmitter coil adjacent to the rail.

Preferably, the magnetic induction detector comprises a receiver coil.

Preferably, the receiver coil has a dimension in a third direction orthogonal to the longitudinal direction of the calibration system, and orthogonal to the direction of the transverse magnetic field, that is larger than the dimension of the rail in that direction. This provides the advantage that alignment of the receiver coil in the third direction is not critical.

When the substantially saddle-shaped transmitter coil is placed over the top of the rail, the length of the transmitter coil in the longitudinal direction of the rail is preferably at least four times larger than a height of the substantially saddle-shaped transmitter coil in a vertically upward direction substantially orthogonal to the rail. In this case preferably the substantially saddle-shaped transmitter coil is arranged for generating the magnetic field in a, substantially, vertical direction at or near the centre of the transmitter coil. Then, the induction detector, e.g. the receiver coil, is preferably placed above the top of the rail at or near the center of the transmitter coil.

Preferably, the length of the transmitter coil in the longitudinal direction of the rail is at least six times, more preferably at least ten times, larger than a dimension of first and/or second incomplete turn measured in the direction substantially orthogonal to the rail.

The invention also relates to a measurement system for calibrating and measuring mechanical stress in at least a part of a rail, for instance a rail for guiding means of transport, on the basis of magnetizability of the respective part of a rail. Said measurement system is arranged for, in use, having a longitudinal direction thereof aligned with a longitudinal direction of at least the part of the rail. The measurement system is provided with a first magnetic field generator for generating at least one predetermined changing magnetic field in a direction transverse to the longitudinal direction. The measurement system comprises a first magnetic induction detector arranged for measuring a magnetic induction oriented in the direction transverse to the longitudinal direction. The measurement system is further provided with a second magnetic field generator for generating at least one predetermined changing magnetic field in the longitudinal direction. The measurement system comprises a second magnetic induction detector arranged for measuring a magnetic induction oriented in the longitudinal direction. The measurement system includes a processing unit arranged for determining a reference induction, representative of a stressless situation of at least the part of the rail under test, on the basis of the measured magnetic induction oriented in the direction transverse to the longitudinal direction. The processing unit is further arranged for determining a mechanical stress in the longitudinal direction of the rail on the basis of the measured magnetic induction oriented in the longitudinal direction and the reference induction.

It is possible that the first magnetic field generator and the second magnetic field generator are one and the same.

Preferably, the first magnetic field generator comprises a substantially saddle-shaped transmitter coil arranged to, in use, be placed partly around the rail and to extend, in use, substantially in the longitudinal direction of the rail on either side of the rail. The length of the transmitter coil in the longitudinal direction is at least four times larger than a dimension of the substantially saddle-shaped coil measured in a direction substantially orthogonal to the longitudinal direction.

Preferably, the substantially saddle-shaped transmitter coil comprises a first incomplete electrically conductive turn, arranged to be placed partly around the rail, and a second incomplete electrically conductive turn, arranged to be placed partly around the rail. The first and/or second incomplete turns may be substantially U-shaped so as to be placed partly around the rail. The first and/or second incomplete turn may extend in a plane that includes at least one direction orthogonal to the longitudinal direction. Preferably, each of the first and second incomplete turns each in its own plane that is substantially orthogonal to the longitudinal direction. The first and the second incomplete turn are mutually electrically conductively connected by a first and/or second longitudinal part extending, in use, substantially in the longitudinal direction of the calibration system, on either side of the rail.

The first and/or second longitudinal parts of the transmitting coil may form the first magnetic field generator arranged for generating magnetic field components in a direction orthogonal to the longitudinal direction of the rail. These magnetic field components are usable for determining the transverse magnetizability of the rail in the direction transverse to the longitudinal direction of the rail. This transverse magnetizability is representative of the rail without mechanical stress. The first and second incomplete electrically conductive turns may form the second magnetic field generator arranged for generating magnetic field components in the longitudinal direction of the rail. These magnetic field components are usable for determining the longitudinal magnetizability of the rail in the longitudinal direction of the rail. This longitudinal magnetizability is representative of mechanical stress in at least the part of the rail. This allows the determination of a compressive or tensile force substantially directed parallel to the longitudinal direction of the respective part of the rail, since the magnetizability (magnetic induction) of the rail in the direction of the magnetic field, which depends on the mechanical stresses which are present, can be determined.

In particular, it may hold that the magnetic field generator(s) comprise(s) at least one electrically conductive turn for generating the magnetic field. This offers the advantage that the magnitude of the magnetic field to be generated can accurately be determined. This is because the strength of a magnetic field inside, for instance, a coil is proportional to the number of turns and to the strength of an electrical current to be fed through these turns.

Preferably, the second magnetic induction detector includes at least one electrically conductive turn for detecting the magnetic induction.

It preferably holds that the at least one turn of the second magnetic induction detector is arranged to be placed, at least partly, around the rail. This offers the advantage that the rail is located in a position where the magnetic field can be considered known and optimally defined. As a result, the so-called Villari effect can be determined as well as possible so that even a relatively low mechanical stress can be detected and an accurate determination of a relatively high mechanical stress becomes possible.

It is possible that at least a part of the turn of the second magnetic induction detector comprises an electrically conductive plate part. Such a plate part may simply be placed below, or above, the rail between supports of the respective part of the rail. Further, determining a distance between the turn and the rail is fairly unambiguous, which is favorable to the reproducibility of the measurement on, for instance, different parts of the rail.

It is possible for the magnetic induction detector(s) to be arranged for determining magnetic induction in the respective part of the rail. Thus, the response of the rail to its being located in the magnetic field is determined directly. In this case, derived effects with relations between the magnetic induction and the derived effect are not in order and therefore preclude potential systematic and/or other errors.

It is possible for the second magnetic induction detector to be provided with a measuring coil for measuring a magnetic induction in the respective part of the rail. The position of the measuring coil with respect to the respective part of the rail can be determined very accurately, which is favorable to the reproducibility of the measurement. In a special embodiment, it holds that the calibration system and/or the measurement system are substantially movable in a longitudinal direction of the respective part of the rail along a predetermined path such that successive parts of the rail are successively in the magnetic field, and that, of these successive parts, the responses to their being located in the magnetic field can be determined. Thus, in an efficient and reproducible manner, on many mutually different parts of the rail, it can be determined whether mechanical stresses are present in the respective parts of the rail. It is also possible to determine the reference inductions and/or mechanical stresses relative to one another. That is, a stress curve related to a longitudinal direction of the rail will be obtained in that case. So-called peak stresses can then be observed relatively simply.

It is, for instance, possible for the calibration system and/or the measurement system to be provided with a mobile device for wheeling said system along the rail and optionally over the rail such that successive parts of the rail are successively in the magnetic field, and that, of these successive parts, the responses to their being located in the magnetic field can be determined. It is also possible for the calibration system and/or the measurement system to be movable along a “rail” which has, for instance, been built exclusively for guiding the system. This latter embodiment offers the advantage that the rail in which the mechanical stresses are to be determined is still available for guiding the means of transport for which this rail was originally intended.

In a special embodiment, it holds that parts of the at least one turn of the second induction detector can be placed in a first relative position and in at least one second relative position, while, in the first relative position, the parts can assume such a predetermined position with respect to a part of a rail that that part of a rail can operatively be included in a predetermined magnetic field, and while, in the at least one second relative position, direct replacement of the at least one turn with the parts again in the first relative position is possible with a part of another rail.

An embodiment of such at least one turn of the second induction detector can at least virtually completely enclose the rail between two supports of the rail. After generating the magnetic field and determining the response of the respective part included in the magnetic field, the at least one turn can brought into the second position. This second position allows the at least one turn to be moved from a part of the rail enclosed by a turn of the magnetic field generator, which part is located on one side of a support, to a part of the rail located on another side of that support.

It is possible for the respective parts of the at least one turn of the second induction detector to be connected with one another in both the first position and in the at least one second position. As a result, moving the at least one turn can be a fairly uncomplicated and simple operation.

In particular, it may hold that the at least one turn of the second induction detector comprises a hinge connection. This further facilitates a simple operation of moving the at least one turn from a part of the rail located on one side of a support to a part of the rail located on another side of that support. In particular, it holds that the respective parts of the at least one turn together form a continuous whole in the first relative position and form an interrupted whole in the at least one second position. Thus, a magnetic induction may be detected in a direction parallel to a longitudinal direction of the rail. This is because the at least one turn can be provided around the rail. The respective parts of the turn are then in the first relative position and can be considered a whole closed upon itself. If necessary, the at least one turn can be removed again. The respective parts of the at least one turn are then brought into one of the second relative positions, the whole originally closed upon itself being interrupted. The respective parts can then be provided elsewhere around the rail again. It is still one of the possibilities of such a measurement system to detect the magnetic induction on other parts of the rail as well with the aid of the same measurement system without requiring too many complicated operations.

It is also possible that parts of the second induction detector can be placed in a first relative position and in at least one second relative position, while, in the first relative position, those parts can assume a predetermined position with respect to a part of the rail and while, in the at least one second relative position, a distance between the parts of the measuring system in a predetermined direction is larger than the distance between those parts in the first relative position. This also creates the possibility that, in the first position, the second induction detector can adequately determine a response of the part of the rail located in a magnetic field by enclosing that part tightly. Then, the respective parts of the second induction detector can be brought into a second position and thus be removed from the respective part in order to then be provided at, for instance, another part of the rail.

Here, it may also hold that the respective parts of the second induction detector remain connected with one another in both the first and the at least one second position. This can create a very conveniently arranged second induction detector. The respective parts of the second induction detector are very well manageable. It is also possible for the second induction detector to comprise a hinge connection. Further, it may also hold that parts of the second induction detector together form a continuous whole in the first relative position and form an interrupted whole in the second position.

In a further embodiment, it may hold that the calibration system and/or the measurement system is provided with a speedometer for determining a speed of movement at which the predetermined magnetic field generator(s) operatively move(s) in a longitudinal direction of the respective part of the rail. This embodiment is advantageous when this embodiment is combined with the above discussed embodiment in which the magnetic field generator(s) and the induction detector(s) are movable along a predetermined path such that successive parts of the rail are successively located in the magnetic field, and in which the responses of these successive parts on their being located in the magnetic field can be determined. The measurement data may, for instance, be stored as a function of time. When the starting position and the speed of the system are known, the measurement data can be related to positions on parts of the rail.

In particular, it may hold that the calibration system and/or the measurement system is provided with a mobile device for wheeling the magnetic field generator(s) and the induction detector(s) along the rail and optionally over the rail such that successive parts of the rail are successively located in the magnetic field and that the responses of these successive parts on their being located in the magnetic field can be determined. This allows an accurate location. The magnetic field generator(s) and the induction detector(s) can accurately be positioned with respect to each respective part of the rail. Further, this allows a relatively quick method for determining reference inductions and/or detecting mechanical stresses in a longitudinal part of a rail.

It may further hold that the measurement system is arranged for quantitatively determining the presence of a mechanical stress in a part of the rail. Here, use may be made of a predetermined relation between a response of the part of the rail located in a magnetic field and a mechanical stress which is present. In particular, it holds that this is relatively well known for the magnetic induction in the mechanical stress. Further, this relation can be predetermined experimentally.

The invention further relates to a method for at least detecting a mechanical stress in at least a part of a rail. In particular, it may hold that the rail comprises a train rail.

The invention is now explained in more detail with reference to a drawing, in which:

FIG. 1 schematically shows a first embodiment of a system for measuring mechanical stress in a rail;

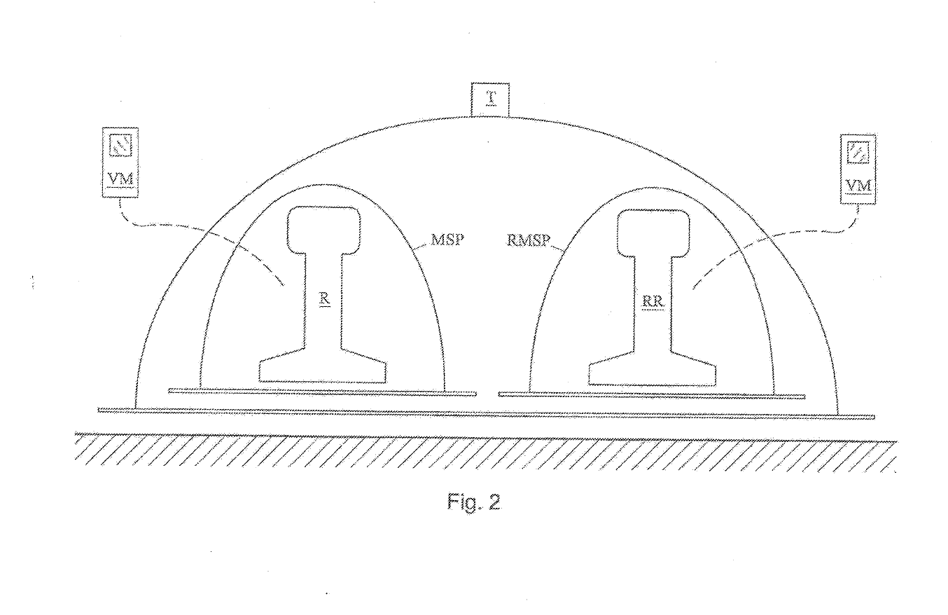

FIG. 2 schematically shows a second embodiment of a system for measuring mechanical stress in a rail;

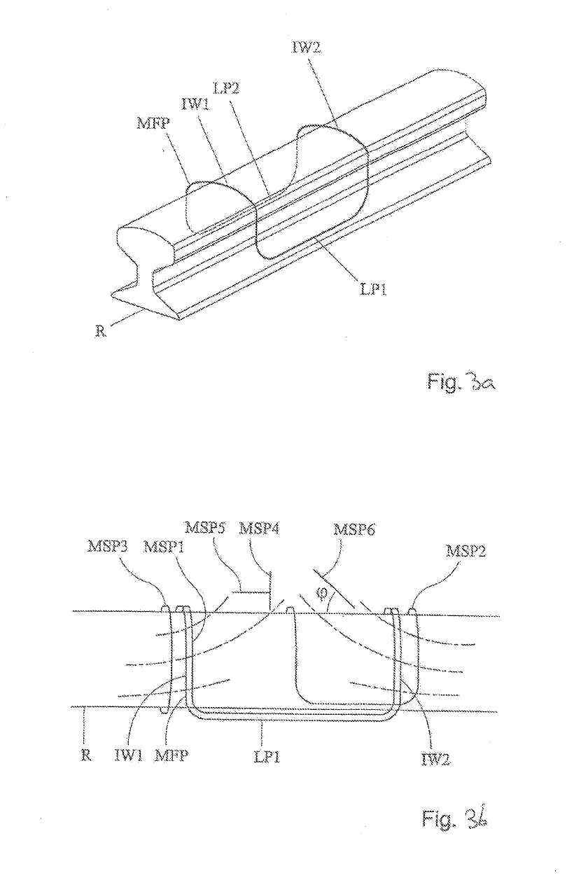

FIG. 3a schematically shows a part of a third embodiment of a system for measuring mechanical stress in a rail;

FIG. 3b schematically shows a side-elevational view of a part of the third embodiment shown in FIG. 3a;

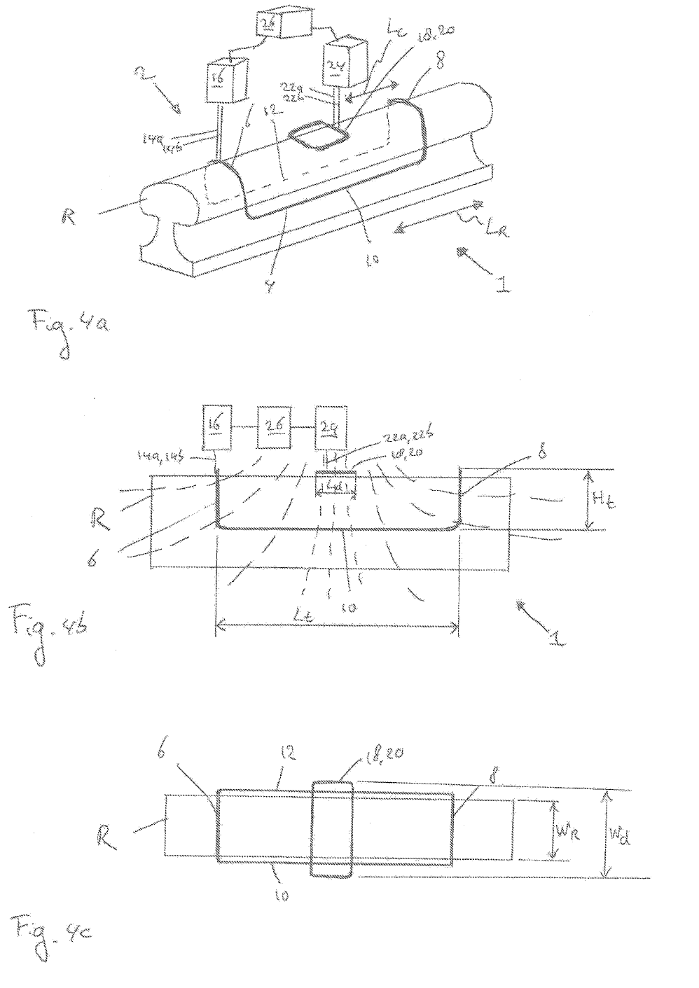

FIGS. 4a-4c schematically show a calibration system for determining a transverse induction in a rail;

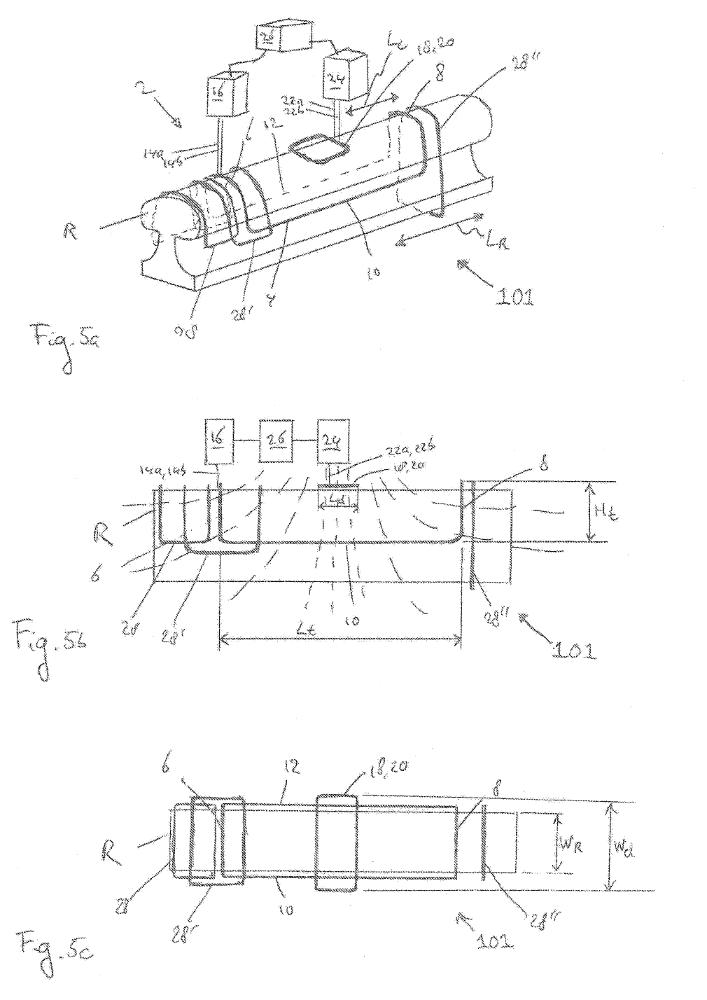

FIGS. 5a-5c schematically show a measurement system for according to the invention;

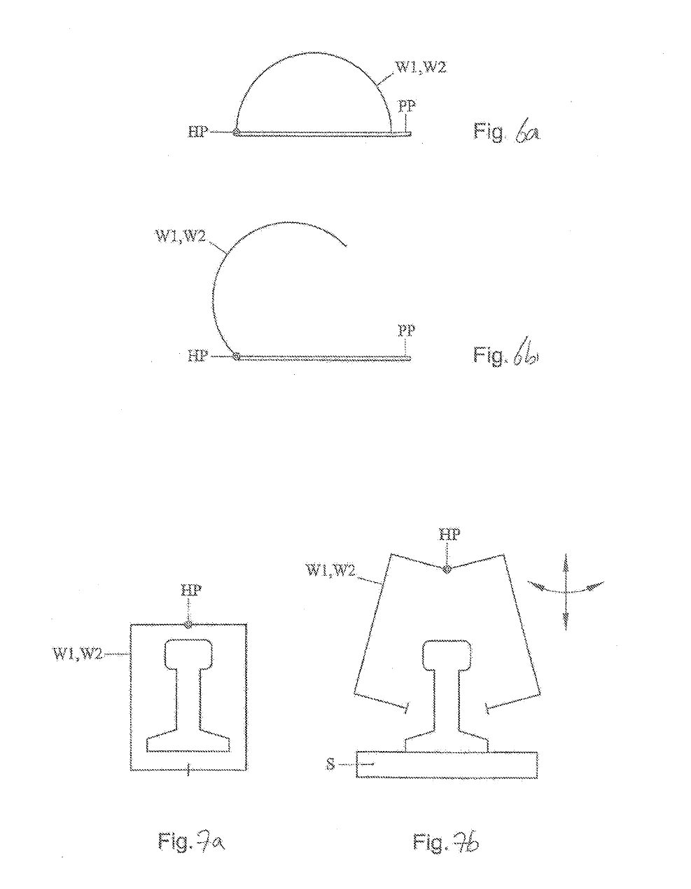

FIG. 6a schematically shows a part of another embodiment of a system for measuring stress in a rail;

FIG. 6b schematically shows the part shown in FIG. 6a;

FIG. 7a schematically shows a part of another embodiment of a system for measuring stress in a rail; and

FIG. 7b schematically shows the part shown in FIG. 7a;

In the drawing, same parts have same reference symbols.

FIG. 1 shows a first embodiment of a system for at least detecting a mechanical stress in at least a part R of a rail. This may, for instance, be a rail for guiding means of transport such as for instance a train. However, it may also be a rail used for transporting a subway train, streetcar or even a “monorail”. The means of transport is usually on the rail and there is usually a set of two rails. However, it is not precluded that the system and the method for at least detecting the mechanical stress in a part of the rail as will be described hereinafter can also be used for a rail from which a means of transport is suspended.

Although the system is at least arranged for, optionally relatively, detecting a presence of a mechanical stress, the system is preferably arranged for determining a mechanical stress qualitatively and still more preferably even quantitatively.

The system is arranged for detecting and optionally quantifying a mechanical stress in a respective part of a rail on the basis of magnetizability of that part. To that end, the system is provided with a magnetic field generator MFP for generating a predetermined magnetic field such that the respective part R of a rail is located in that field. The system is further provided with a measuring system MS for determining a response of the respective part R of a rail to its being located in the magnetic field. To this end, a changing magnetic field is present in the respective part of the rail.

As shown in FIG. 1, the magnetic field generator MFP may, for instance, comprise one or more electrically conductive turns W1. In this turn, a transformer T may be included for supplying the current required. There will usually be a plurality of electrically conductive turns. It is possible that one turn “goes through” the transformer and two turns around the rail. When an electrical current is fed through the electrically conductive turn W1, a magnetic field H is generated within the turns. The strength of the magnetic field is proportional to the number of turns W1 and the strength of the current fed through. The magnetic field generator may be provided with a current meter (not shown) for determining the current intensity fed through the turns W1. A current meter may also, or alternatively, be part of the measuring system to be discussed in more detail. The embodiment shown in FIG. 1 is arranged for generating a magnetic field extending substantially parallel to the longitudinal direction of the respective part R of the rail. It will be clear that, here in this example, the magnetic field generator is positioned statically. It will further be clear that the magnetic field thus extends in a predetermined direction with respect to the respective part R of the rail. For FIG. 1, it holds that the longitudinal direction of the respective part R of the rail is perpendicular to the plane in which FIG. 1 is shown. As can be seen, in this example, it holds that the turn shown is arranged to be placed around the rail. This is usually possible since parts R of the rail are located above the base G and there is often a free space between the rail and the base G.

It is possible for at least a part of the turn W1 to comprise an electrically conductive plate part PP1. As drawn, this plate may have a straight design. However, it is not precluded that this plate PP1 is also, at least partly, provided with a curve. Herein, plate part is understood to mean a part which is suitable for feeding an electrical current, such as a bar, strip, tube, section and/or cable.

The measuring system MS is preferably arranged for determining magnetic induction in the respective part of the rail R. In the example shown in FIG. 1, the measuring system is provided with a measuring coil MSP for measuring the change of magnetic induction B in the respective part R of the rail. The respective part of the rail R is understood to mean the part of the rail R of which the mechanical stress is to be determined. As can be seen, in this example, it holds that the measuring coil shown is arranged to be placed around the rail, and that the measuring coil has the same orientation with respect to the rail as the turn of the magnetic field generator. The measuring coil thus encloses the respective part of the rail. Thus, the measuring coil further has a predetermined orientation with respect to the respective part of the rail. It will be clear that, here in this example, the measuring coil is positioned statically. The measuring system is therefore arranged for measuring the magnetic induction in the direction of the predetermined magnetic field generated by the magnetic field generator. In this example, the measuring system is therefore arranged for determining the magnetic induction in the respective part of the rail in the longitudinal direction of the respective part of the rail. The measuring coil MSP may comprise one or more turns W2. These are again electrically conductive turns W2. The measuring system is provided with a voltmeter VM for measuring a voltage over the measuring coil MSP. This voltage is proportional to the change in the magnetic induction per time unit and can be determined with the aid of formulas very well known per se to a skilled person.

FIG. 2 again shows the system of FIG. 1. This FIG. 2 shows how this system could be calibrated according to the prior art. Thereto a magnetizable reference object was provided with an, optionally predetermined, magnetizability corresponding with the magnetizability of the rail to be examined. This reference object, for instance, would have been a part RR of a rail which is not used as a rail. Preferably, this part RR was of the same “batch” as the rail of which it does need to be measured what stresses occur therein. The reference object could, for instance, have a stressless design and/or could be used for determining a magnetization such as it is possible with a part RR of a rail not exposed to the conditions to which a rail is exposed in operative condition. According to this prior art embodiment, it was possible to determine the magnetizability of the rail R in relation to the magnetizability of the reference rail RR.

In the prior art embodiment shown in FIG. 2, the measuring system further comprise a reference measuring coil RMSP for determining the magnetic induction in the reference object RR. As can be seen, in this example, it holds that the measuring coil MSP, the reference measuring coil RMSP and the turn of the magnetic field generator MFP are arranged to be placed around the rail. It can also be seen that the measuring coil MSP has the same orientation with respect to the respective part of the rail as the turn of the magnetic field generator. It can further be seen that the reference measuring coil RMSP has the same orientation with respect to the respective part of the reference rail as the turn of the magnetic field generator. It will be clear that, in this prior art embodiment, the magnetic field generator, the measuring coil and the reference measuring coil are positioned statically. There may be one voltmeter VM which alternately measures a voltage over a measuring coil MSP and the voltage over reference measuring coil RMSP. There may also be two voltmeters, one of which being arranged to measure the voltage over a measuring coil MSP and one of which being arranged to measure the voltage over RMSP.

FIGS. 3a and 3b schematically show a part of a second embodiment of the system for at least detecting a mechanical stress in at least a part R of a rail. In this example, the magnetic field generator MFP comprises a first incomplete electrically conductive turn IW1, in this example a substantially three-quarter turn, which partly enclosed the respective part of the rail R. The first incomplete turn is substantially U-shaped. The first incomplete turn is therefore arranged to be placed partly around the rail. In this example, the magnetic field generator MFP comprises a second incomplete electrically conductive turn IW2, in this example a substantially three-quarter turn, which partly encloses the respective part of the rail R. The second incomplete turn is substantially U-shaped. The second incomplete turn is therefore arranged to be placed partly around the rail. In FIG. 3a, the first and the second incomplete turn are mutually electrically conductively connected by a first and/or a second longitudinal part LP1, LP2 extending substantially in the longitudinal direction of the rail on either side of the rail. Thus, in this example, the two incomplete turns IW1, IW2 and the longitudinal parts LP1, LP2 of the magnetic field generator together form a turn which at least partly encloses the respective part of the rail. If a current runs through the turn, each incomplete turn IW1, IW2 will generate a magnetic field, the magnetic field generated by the first turn IW1 being directed substantially opposite to the magnetic field generated by the second turn IW2. In order to effectively generate a magnetic field near the first and second turn IW1, IW2, the first turn and second turn are preferably placed at a distance from each other. FIG. 3b shows a side elevational view of the embodiment shown in FIG. 3a in which field lines of the magnetic fields are drawn as dash-dotted lines. Thus, the magnetic field generated by the magnetic field generator MFP has a predetermined direction with respect to the respective part of the rail. It will be clear that the magnetic field generator thus formed may also comprise a plurality of turns.

In the embodiment shown in FIGS. 3a and 3b, the measuring system may comprise a measuring coil MSP. The measuring coil may, for instance, comprises an electrically conductive turn having a form similar to the form of the turn of the magnetic field generator MFP shown in FIG. 3a. In an embodiment, the measuring coil MSP1 is wound along with the turn of the magnetic field generator. Thus, the magnetic field generator MFP and the measuring coil MSP1 form a whole, e.g. by means of potting, as shown in FIG. 3b. In an alternative embodiment, a first incomplete turn of the measuring coil MSP2 is located between the first and the second incomplete turn IW1, IW2 of the magnetic field generator MFP in the longitudinal direction of the rail, in this example substantially in the middle between the first and the second incomplete turn IW1, IW2. A second incomplete turn of the measuring coil MSP2 is placed near the turn of the magnetic field generator MFP. In FIG. 3b, the second incomplete turn of the measuring coil MSP2 is placed outside the first and the second incomplete turn IW1, IW2, and it will be clear that the second incomplete turn of the measuring coil MSP2 may also be placed between the first and the second incomplete turn IW1, IW2. The measuring coil MSP2 and the turn of the magnetic field generator MFP both at least partly enclose the respective part of the rail R, see FIG. 3b.

The measuring system may also comprise a measuring coil MSP3 (see FIG. 3b) with a turn enclosing the respective part of the rail, for instance as described with reference to FIG. 1 or 2. Preferably, the measuring coil MSP3 is located near the turn of the magnetic field generator MFP.

In an alternative embodiment, the measuring system comprises a first measuring coil MSP4 extending in a plane which is transverse to the respective part of the rail and a second measuring coil MSP5 extending in a plane extending in the longitudinal direction of the rail. In the example of FIG. 3b, both measuring coils MSP4, MSP5, are located above the head of the respective part of the rail. The first measuring coil MSP4 is used for measuring a first component of the magnetic induction in the longitudinal direction of the respective part of the rail, in this example the horizontal direction, at the location above the head of the respective part of the rail. The second measuring coil MSP5 is used for measuring a second component of the magnetic induction in a direction transverse to the longitudinal direction of the respective part of the rail, in this example the vertical direction, at the location above the head of the respective part of the rail. Here, the ratio of the first component and the second component of the magnetic induction is a measure for the presence of mechanical stress in the respective part of the rail. This ratio, also referred to as cotangent, is expressed as the first component divided by the second component. According to WO 2006/080838, a reference cotangent can be determined as the cotangent determined on a reference rail which is free from mechanical stress. If the cotangent is determined on a part of a rail to be measured, it can be compared with the reference cotangent. On the basis of the fact that the measured cotangent is larger or smaller than the reference cotangent, it can be determined that a tensile stress or compressive stress is present in the respective part of the rail. If the measured cotangent is larger than the reference cotangent, for instance tensile stress may be present in the respective part of the rail. If the measured cotangent is smaller than the reference cotangent, for instance compressive stress may be present in the respective part of the rail. Preferably, the magnitude of the tensile stress or compressive stress which is present is determined on the basis of the extent to which the measured cotangent differs from the reference cotangent.

In an alternative embodiment, the measuring system comprises a rotatably arranged measuring coil MSP6, see FIG. 3b. In this example, a centerline of the measuring coil MSP6 is located in a vertical plane through the longitudinal axis of the respective part of the rail. Preferably, the measuring coil MSP6 is provided with an angle indication for being able to determine the angle, φ, included by the measuring coil MSP6 and the longitudinal axis of the rail when the measuring coil MSP6 is positioned such that a minimal magnetic induction is measured. Here, the size of the angle φ is a measure for the presence of mechanical stress in the respective part of the rail. According to WO 2006/080838 a reference angle can be determined if the angle determined on a reference rail is free from mechanical stress. If the angle is determined on a part of a rail to be measured, it can be compared with the reference angle. On the basis of the fact that the measured angle is larger or smaller than the reference angle, it can be determined that a tensile stress or compressive stress is present in the respective part of the rail. If the measured angle is smaller than the reference angle, for instance a tensile stress may be present in the respective part of the rail. If the measured angle is smaller than the reference cotangent, for instance compressive stress may be present in the respective part of the rail. Preferably, the magnitude of the tensile stress or compressive stress which is present is determined n the basis of the extent to which the measured angle differs from the reference angle. In the example, the angle φ included by the measuring coil MSP6 and the longitudinal axis of the rail is determined when the measuring coil MSP6 is positioned such that a minimal magnetic induction is measured. It will be clear that it is also possible that the angle φ included by the measuring coil MSP6 and the longitudinal axis of the rail is determined when the measuring coil MSP6 is positioned such that a maximal magnetic induction is measured.

From WO 2006/080838 it is known that it is possible that the embodiment shown in FIG. 1 is further provided with a measuring system arranged for measuring the magnetic induction in the direction transverse to the longitudinal direction of the respective part of the rail, and optionally with a second magnetic field generator, which generates a magnetic field extending in a direction transverse to the longitudinal direction of the respective part of the rail. It had been found that, since the magnetizability of the rail in the direction transverse to the longitudinal direction of the respective part of the rail does not or hardly change and/or changes differently from the magnetizability in the longitudinal direction of the respective part of the rail as a result of mechanical stresses in the longitudinal direction of the respective part of the rail, the magnetic induction in the direction transverse to the longitudinal direction of the respective part of the rail could be used as a reference value for a stressless situation in the respective part of the rail. Thus, no separate reference object would be necessary.

The present invention aims to provide a calibration device arranged for determining the magnetizability of the rail in the direction transverse to the longitudinal direction of the respective part of the rail. New experiments by the inventors have shown that a calibration system for measuring such transverse magnetizability is preferably designed in a specific way in order to optimize sensitivity, allow easy implementation, etc. FIG. 4a shows an embodiment of a calibration system 1 according to the invention.

In the example of FIG. 4a the calibration system 1 has a longitudinal direction L_{c} thereof aligned with a longitudinal direction L_{R} of a part of a rail (R) to be measured. The calibration system 1 includes a magnetic field generator 2. The magnetic field generator 2 comprises a substantially saddle-shaped transmitter coil 4.

In FIG. 4a, the substantially saddle-shaped transmitter coil 4 comprises a first incomplete electrically conductive turn 6 arranged to be placed partly around the rail. The first incomplete turn 6 is in this example substantially U-shaped. In FIG. 4a, the substantially saddle-shaped transmitter coil 4 further comprises a second incomplete electrically conductive turn 8 arranged to be placed partly around the rail. The second incomplete turn 8 is in this example substantially U-shaped. In FIG. 4a, the substantially saddle-shaped transmitter coil 4 further comprises a first longitudinal part 10 electrically connecting the first and second incomplete turns 4,6. The first longitudinal part 10 extends substantially in the longitudinal direction L_{c} of the calibration system. In FIG. 4a, the substantially saddle-shaped transmitter coil 4 further comprises a second longitudinal part 12 electrically connecting the first and second incomplete turns 4,6. The second longitudinal part 12 extends substantially in the longitudinal direction L_{c} of the calibration system on the opposite side of the rail R. In this example, also the second incomplete turn 8 extends in a plane that is substantially orthogonal to the longitudinal direction L_{c}.

The transmitter coil 4 comprises electrical connections 14a,14b for connecting the coil 4 to a signal generator 16, such as a current source or voltage source. The signal generator 16 supplies electrical energy to the transmitter coil 4, such that the transmitter coil 4 generates a magnetic field. Preferably the magnetic field is a changing magnetic field, such as a periodic magnetic field. The changing magnetic field may have a frequency of for instance between 20 and 200 Hz, e.g. having a frequency of about 50 or 60 Hz.

FIG. 4b shows a schematic side view of the system of FIG. 4a. In FIG. 4b magnetic field lines F indicating the local direction of the magnetic field are schematically indicated with dashed lines. It will be appreciated that at and near the center of the transmitter coil 4 the magnetic field generated by the transmitter coil is substantially transverse to the longitudinal direction of the Rail R, in this example vertically.

The calibration system of FIG. 4a further comprises a magnetic induction detector 18. The magnetic induction detector 18 is arranged for measuring a magnetic induction oriented in the direction transverse to the longitudinal direction. In this example the magnetic induction detector 18 includes a receiver coil 20. The receiver coil 20 is positioned at or near the center of the transmitter coil 4, above the rail R. The receiver coil 20 is therefore arranged for detecting a vertical induction near the rail R. The induction detector 18 comprises electrical connections 22a,22b for connecting the induction detector 18 to a receiver 24. The receiver 24 determines a signal representative of the induction detected by the induction detector 18.

In this example, a length Lₜ of the transmitter coil 4, measured in the longitudinal direction L_{c}, is approximately 1.2 m. This dimension, in this example corresponds to approximately twice a hart-to-heart distance of railway sleepers supporting the rail R. This way, the induction detector 18 can be positioned approximately midway between two sleepers, while the first and second incomplete turns 6,8 are also positioned approximately midway between two (adjacent) sleepers. Hence, both the induction detector 18 and the incomplete turns 6,8 can be placed as far as possible away from magnetically disturbing elements such as the fixing means that fix the rail to the sleepers. This improves the accuracy of the determination of the transverse magnetization (and longitudinal magnetization). This also makes positioning of the calibration system with respect to the sleepers less critical.

In this example, the first and second longitudinal parts 10,12 extends at or near a half height of the rail R. This provides the advantage that a magnetic field is generated in the head part of the rail R. In this example, the first incomplete turn 6 extends in a plane that is substantially orthogonal to the longitudinal direction L_{c}. In this example the rail is approximately 16 cm high. Therefore, a height Hₜ of the substantially saddle-shaped coil 4 in this example is approximately 8 cm.

Hence, in this example the length Lₜ of the transmitter coil 4 is approximately fifteen times larger than the height Hₜ of the substantially saddle-shaped transmitter coil 4. As can be seen in FIG. 4b this provides the advantage that the magnetic field at and near the center of the substantially saddle-shaped transmitter coil 4 is substantially oriented transverse to the longitudinal direction L_{c}. More in general, the length Lₜ of the transmitter coil 4 is at least four times larger than a height Hₜ of the substantially saddle-shaped coil 4. More in general, the length Lₜ of the transmitter coil, measured in the longitudinal direction L_{c}, is at least four times larger than a dimension of the substantially saddle-shaped coil measured in a direction substantially orthogonal to the longitudinal direction. Preferably, the length Lₜ of the transmitter coil is at least six times, more preferably at least ten times, larger than a dimension of the substantially saddle-shaped coil measured in a direction substantially orthogonal to the longitudinal direction.

In this example, the magnetic induction detector 18 has a length L_{d} in the longitudinal direction L_{c} that is at least five times smaller than the length Lₜ of the transmitter coil 4. Hence, the magnetic induction detector 18 is spatially limited to a portion of the generated magnetic field that is even more substantially transverse to the longitudinal direction L_{c}.

FIG. 4c shows a schematic representation of a top plan view of the calibration system 1 of FIGS. 4a and 4b. In FIG. 4c it can be seen that the magnetic induction detector 18 has a width W_{d} that is larger than the dimension W_{R} of the rail R in that direction. Hence, alignment of the induction detector 18 in a width direction of the rail is not critical, making installation of the calibration system for measurement easier.

Although not shown in FIGS. 4a-4c, the calibration system 1 comprises a housing including both the transmitter coil 4 and the induction detector 18. Hence, the calibration system 1 can be transported and positioned with respect to the rail R as a unitary entity.

The calibration system 1 also comprises a processing unit 26. The processing unit 26 is arranged for determining a reference value representative of the magnetization in the direction transverse to the longitudinal direction on the basis of the induction measured by the induction detector 18. The processing unit 26 may also be arranged for controlling the signal generator 16 and/or the receiver 24. FIG. 5a shows an embodiment of a measurement system 101 according to the invention.

In the example of FIG. 5a the measurement system 101 has a longitudinal direction L_{c} thereof aligned with a longitudinal direction L_{R} of a part of a rail (R) to be measured. The measurement system 1 includes a magnetic field generator 2. The magnetic field generator 2 comprises a substantially saddle-shaped transmitter coil 4 as already described with respect to FIGS. 4a-4c.

FIG. 5b shows a schematic side view of the system of FIG. 5a having the same substantially saddle-shaped transmitter coil 4. In FIG. 5b magnetic field lines F indicating the local direction of the magnetic field are schematically indicated with dashed lines. It will be appreciated that at and near the center of the transmitter coil 4 the magnetic field generated by the transmitter coil 4 is substantially transverse to the longitudinal direction of the Rail R, in this example vertically. It will be appreciated that at and near the incomplete turns 6,8 the magnetic field generated by the transmitter coil 4 is substantially in the longitudinal direction L_{R} of the rail.

The measurement system of FIG. 5a comprises a magnetic induction detector 18 as also shown in FIG. 4a. This magnetic induction detector 18 is also termed first magnetic induction detector 18 with respect to FIGS. 5a-5c. The first magnetic induction detector 18 is arranged for measuring a magnetic induction oriented in the direction transverse to the longitudinal direction L. In this example the first magnetic induction detector 18 includes a receiver coil 20. The receiver coil 20 is positioned at or near the centre of the transmitter coil 4, above the rail R. The receiver coil 20 is therefore arranged for detecting a vertical induction near the rail R. The first induction detector 18 comprises electrical connections 22a, 22b for connecting the first induction detector 18 to a receiver 24. The receiver 24 determines a signal representative of the induction detected by the induction detector 18.

In the example of FIGS. 5a-5c, a length Lₜ of the transmitter coil 4, measured in the longitudinal direction L_{c}, is approximately 1.2 m. In this example, the first and second longitudinal parts 10,12 extend at or near a half height of the rail R. In this example, the first incomplete turn 6 extends in a plane that is substantially orthogonal to the longitudinal direction L_{c}. In this example a height Hₜ of the substantially saddle-shaped coil 4 in this example is approximately 8 cm.

Hence, in this example the length Lₜ of the transmitter coil 4 is approximately fifteen times larger than the height Hₜ of the substantially saddle-shaped transmitter coil 4. As can be seen in FIG. 4b this provides the advantage that the magnetic field at and near the center of the substantially saddle-shaped transmitter coil 4 is substantially oriented transverse to the longitudinal direction L_{c}. More in general, the length Lₜ of the transmitter coil 4 is at least four times larger than a height Hₜ of the substantially saddle-shaped coil 4. More in general, the length Lₜ of the transmitter coil, measured in the longitudinal direction L_{c}, is at least four times larger than a dimension of the substantially saddle-shaped coil measured in a direction substantially orthogonal to the longitudinal direction. Preferably, the length Lₜ of the transmitter coil is at least six times, more preferably at least ten times, larger than a dimension of the substantially saddle-shaped coil measured in a direction substantially orthogonal to the longitudinal direction.

In this example, the first magnetic induction detector 18 has a length L_{d} in the longitudinal direction L_{c} that is at least five times smaller than the length Lₜ of the transmitter coil 4. Hence, the magnetic induction detector 18 is spatially limited to a portion of the generated magnetic field that is even more substantially transverse to the longitudinal direction L_{c}.

The measurement system 101 further includes a second magnetic induction detector. In the example of FIGS. 5a-5c three second magnetic induction detectors 28, 28′, 28″ are shown. It will be appreciated that the measurement system may include one or more of these second induction detectors. The second induction detector may be designed as a substantially saddle-shaped receiver coil 28 as explained with respect to FIG. 3b. This substantially saddle-shaped receiver coil 28 is similar in shape to the substantially saddle-shaped transmitter coil 4. In this example the receiver coil 28 is positioned at an offset with respect to the transmitter coil in the longitudinal direction L_{c}. Herein, the receiver coil 28 may be adjacent to the transmitter coil 4 or adjacent to the transmitter coil (shown as 28′ in FIG. 5b). The second induction detector may also be designed as a substantially ring-shaped receiver coil 28″. The substantially ring-shaped detector coil 28″ is placed around the rail R. It will be appreciated that the second induction detector 28, 28′, 28″ is arranged for detecting a longitudinal induction in the rail R.

In the examples of FIGS. 5a-5c the a processing unit 26 is arranged for determining a reference induction, representative of a stressless situation of at least the part of the rail under test, on the basis of the magnetic induction oriented in the direction transverse to the longitudinal direction, as measured by the first induction detector 18. The processing unit 26 is further arranged for determining a mechanical stress in the longitudinal direction of the rail on the basis of the magnetic induction oriented in the longitudinal direction, as measured by the second induction detector, and the reference induction.

Although not shown in FIGS. 5a-5c, the measurement system 101 may comprise a housing including the transmitter coil 4, the induction detector 18 and the second induction detector (28, 28′ and/or 28″). Hence, the measurement system 101 can be transported and positioned with respect to the rail R as a unitary entity.

It will be clear from the above, and from the Figures, that, in the embodiments shown, the magnetic field generator and the induction detectors may be free from mechanical contact with the respective part of the rail. Thus, the magnetic field generator and the measuring system can be moved in the longitudinal direction of the rail while they are free from mechanical friction with the rail and associated wear.

The system may be provided with a mobile device for wheeling at least a part of the magnetic field generator and at least a part of the induction detector along the rail and optionally over the rail such that successive parts of the rail are successively located in the magnetic field and that the responses of these successive parts to their being located in the magnetic field can be determined.

FIGS. 6a and 6b, and FIGS. 7a and 7b show examples of parts of a second induction detector, namely one turn, or parts of a second magnetic induction detector 28″, also parts of one turn, which are movable substantially in a longitudinal direction of the respective part of the rail along a predetermined path. Here, it may hold that these parts of the second induction detector can be placed in a first relative position, such as for instance shown in FIG. 6a and FIG. 7a, and in at least one second relative position, such as for instance shown in FIGS. 6b and 7b. In the first relative position, the respective parts may assume such a predetermined position with respect to a part R of a rail that part R of a rail can operatively be included in the second induction detector for determining the magnetic induction in the part R of the rail. Here, it will be clear that, in the first relative position, the second induction detector has a predetermined position and orientation with respect to the respective part R of the rail. In the at least one second relative position, a distance between the respective parts is such that direct replacement of the at least one turn with the parts again in the first position is possible at a part of another rail. In this context, “direct” is understood to mean that no winding activities of turns are necessary. It could also be stated that, in the at least one second position, a distance between the parts of the system in a predetermined direction is larger than the distance between those parts in the first relative position. In other words, for the turn as shown in FIGS. 6a, 6b and FIGS. 7a, 7b, it holds that the turn can be placed such that a field extending in a longitudinal direction of the rail can be measured. There where the rail is connected with a support, such as a sleeper, the turn can be temporarily interrupted, i.e. the respective parts can assume the second relative position as shown in FIGS. 6b and 6b, in order to, for instance, move the turn from a part R located on one side of the support S to a position located on another side of the support S. In the examples shown in FIGS. 6a, 6b and FIGS. 7a, 7b, the respective parts remain connected with one another in both the first and the at least one second position. A hinge connection HP ensures that this connection exists and that the parts can assume both the first and the second position with respect to one another. As can be seen in FIGS. 6a and 7a, the respective parts together form a continuous whole in the first relative position, which whole can also be considered as a whole closed upon itself. As can be seen in FIGS. 6b and 7b, the respective parts form an interrupted whole in the second position. It will be clear that the respective parts can also be detachably connectable, so that they are, for instance, nor connected in the second relative position.

It will be clear that, in the examples, the measuring system may also be provided with alternative sensors for measuring magnetic induction, such as for instance Hall sensors.

In general, the system may also be arranged for storing data for detecting the mechanical stress. To this end, the system may be provided with a so-called data storage. The processing unit may also be arranged for quantitatively determining the presence of the mechanical stress in a part of the rail. Here, use can be made of a predetermined relation between the magnetization of a measured part of the rail and the stresses which is present in the rail.

The invention is by no means limited to the embodiments shown.

Incidentally, it holds that the predetermined field, as indicated hereinabove, does not necessarily need to be known. Herein, predetermined is at least understood to mean a field which is sufficiently strong to cause a magnetization of a part of the rail.

In the foregoing specification, the invention has been described with reference to specific examples of embodiments of the invention. It will, however, be evident that various modifications and changes may be made therein without departing from the broader spirit and scope of the invention as set forth in the appended claims.

In a special embodiment, the magnetic field generator is provided with a larger number of turns so that the current to be fed through can be relatively low. Alternatively, it is also possible that the magnetic field generator is provided with a small number of turns, for instance one or two turns, since this offers the advantage that the magnetic field generator can simply be provided at the respective part of the rail.

It has been found that the magnetizability in a rail decreases by about 8% per pressure increase of 100 Mpa. Incidentally, the sensitivity of the measurement depends on the type of rail.

In the example of FIGS. 4a-4c the transmitter coil 4 and the induction detector 18 are part of a unitary device. It will be clear that it is also possible that the transmitter coil 4 and the induction detector 18 are included in mutually separate devices.

In the example of FIGS. 5a-5c a single transmitter coil 4 is used for generating the magnetic field in the longitudinal direction and the magnetic field in the transverse direction. It will be clear that it is also possible to use separate transmitter coils, one for generating the magnetic field in the longitudinal direction, and another for generating the magnetic field in the transverse direction. In the example of FIGS. 5a-5c the first induction detector and the second induction detector are part of a unitary device. It will be clear that it is also possible to provide a first device including a first magnetic field generator for generating the transverse magnetic field and the first induction detector for measuring the transverse induction, and a second device including a second magnetic field generator for generating the longitudinal magnetic field and the second induction detector for measuring the longitudinal induction.

It will be appreciated that the processing unit 26, signal generator 16 and receiver 24 can be embodied as dedicated electronic circuits, possibly including software code portions. The processing unit 26, signal generator 16 and receiver 24 can also be embodied as software code portions executed on, and e.g. stored in a memory of, a programmable apparatus such as a computer.

However, other modifications, variations, and alternatives are also possible. The specifications, drawings and examples are, accordingly, to be regarded in an illustrative rather than in a restrictive sense.

In the claims, any reference signs placed between parentheses shall not be construed as limiting the claim. The word ‘comprising’ does not exclude the presence of other features or steps than those listed in a claim. Furthermore, the words ‘a’ and ‘an’ shall not be construed as limited to ‘only one’, but instead are used to mean ‘at least one’, and do not exclude a plurality. The mere fact that certain measures are recited in mutually different claims does not indicate that a combination of these measures cannot be used to advantage.

1. Calibration system for measuring the magnetizability of at least a part of a rail, for instance a rail for guiding means of transport, the system being arranged for, in use, having a longitudinal direction thereof aligned with a longitudinal direction of at least the part of the rail, the system being provided with
a magnetic field generator for generating at least one predetermined changing magnetic field in a direction transverse to a longitudinal direction, the magnetic field generator comprising a substantially saddle-shaped transmitter coil arranged to, in use, be placed partly around the rail and to extend, in use, substantially in the longitudinal direction of the rail on either side of the rail, and
a magnetic induction detector arranged for measuring a magnetic induction oriented in the direction transverse to the longitudinal direction, wherein a length of the transmitter coil, measured in the longitudinal direction, is at least four times larger than a dimension of the substantially saddle-shaped coil measured in a direction substantially orthogonal to the longitudinal direction.

2. Calibration system according to claim 1, wherein the magnetic induction detector has a dimension in the longitudinal direction that is at least five times smaller than the length of the transmitter coil.

3. Calibration system according to claim 1, wherein the magnetic induction detector comprises a receiver coil.

4. Calibration system according to claim 1, wherein the magnetic induction detector has a dimension in a direction orthogonal to the longitudinal direction that is larger than the dimension of the rail in that direction.

5. Calibration system according to claim 1, wherein the length of the transmitter coil is larger, preferably at least twice larger, than a heart-to-heart distance of adjacent rail sleepers.

6. Calibration system according to claim 1, wherein the substantially saddle-shaped transmitter coil comprises a first incomplete, substantially U-shaped, electrically conductive turn, arranged to be placed partly around the rail, a second incomplete, substantially U-shaped, electrically conductive turn, arranged to be placed partly around the rail, and a first and second longitudinal part extending, in use, substantially in the longitudinal direction of the calibration system, on either side of the rail.

7. Calibration system according to claim 6, wherein the substantially saddle-shaped transmitter coil is arranged such that, in use, the first and/or second longitudinal part extends at or near a half height of the rail.

8. Calibration system according to claim 6, wherein each of the first and second incomplete turns extends each in its own plane that is substantially orthogonal to the longitudinal direction.

9. Calibration system according to claim 6, wherein a height of the first and/or second incomplete turn, measured in a vertical direction in use, is at least four times smaller than the length of the transmitter coil.

10. Calibration system according to claim 1, wherein the induction detector is arranged such that, in use, the induction detector is positioned above the rail at or near a center of the transmitter coil.

11. Calibration system according to claim 1, comprising a housing including both the transmitter coil and the induction detector.

12. Calibration system according to claim 1 in combination with a measuring system including:
a magnetic field generator for generating at least one predetermined changing magnetic field in the longitudinal direction;
a magnetic induction detector arranged for measuring a magnetic induction oriented in the longitudinal direction; and
a processing unit arranged for:
determining a reference induction, representative of a stressless situation of at least the part of the rail under test, on the basis of the measured magnetic induction oriented in the direction transverse to the longitudinal direction; and
determining a mechanical stress in the longitudinal direction of the rail on the basis of the measured magnetic induction oriented in the longitudinal direction and the reference induction.

13. Measurement system for calibrating and measuring mechanical stress in at least a part of a rail, for instance a rail for guiding means of transport, on the basis of magnetizability of the respective part of a rail,
said measurement system being arranged for, in use, having a longitudinal direction thereof aligned with a longitudinal direction of at least the part of the rail,
the measurement system including:
a first magnetic field generator for generating at least one predetermined changing magnetic field in a direction transverse to the longitudinal direction;
a first magnetic induction detector arranged for measuring a magnetic induction oriented in the direction transverse to the longitudinal direction;
a second magnetic field generator for generating at least one predetermined changing magnetic field in the longitudinal direction;
a second magnetic induction detector arranged for measuring a magnetic induction oriented in the longitudinal direction; and
a processing unit arranged for:
determining a reference induction, representative of a stressless situation of at least the part of the rail under test, on the basis of the measured magnetic induction oriented in the direction transverse to the longitudinal direction; and
determining a mechanical stress in the longitudinal direction of the rail on the basis of the measured magnetic induction oriented in the longitudinal direction and the reference induction.

14. Measurement system according to claim 13, wherein the first magnetic field generator and the second magnetic field generator are one and the same.

15. Measurement system according to claim 13, wherein the first magnetic field generator comprises a substantially saddle-shaped transmitter coil arranged to, in use, be placed partly around the rail and to extend, in use, substantially in the longitudinal direction of the rail on either side of the rail.

16. Measurement system according to claim 13, wherein the second magnetic field generator comprises a substantially saddle-shaped transmitter coil arranged to, in use, be placed partly around the rail and to extend, in use, substantially in the longitudinal direction of the rail on either side of the rail.

17. Measurement system according to claim 15, wherein the length of the transmitter coil in the longitudinal direction is at least four times larger than a dimension of the substantially saddle-shaped coil measured in a direction substantially orthogonal to the longitudinal direction.

18. Measurement system according to claim 15, wherein the substantially saddle-shaped transmitter coil comprises a first incomplete, substantially U-shaped, electrically conductive turn, arranged to be placed partly around the rail, a second incomplete, substantially U-shaped, electrically conductive turn, arranged to be placed partly around the rail, and a first and second longitudinal part extending, in use, substantially in the longitudinal direction of the calibration system, on either side of the rail.

19-22. (canceled)

23. Measurement system according to claim 13, wherein the magnetic induction detector comprises a receiver coil.

24-27. (canceled)

28. Measurement system according to claim 13, wherein the second induction detector comprises a measuring coil including at least one electrically conductive turn arranged to be able to be placed at least partly around the rail.

29. Measurement system according to claim 28, wherein the at least one turn of the second induction detector is arranged to be able to be placed around the rail.

30. Measurement system according to claim 28, wherein at least a part of the turn of the second induction detector comprises an electrically conductive plate part.

31. Measurement system according to claim 13, wherein the calibration system and/or the measurement system are movable substantially in a longitudinal direction of a rail along a predetermined path such that successive parts of the rail are successively located in the magnetic field and that the responses of these successive parts on their being located in the magnetic field can be measured.

32. Measurement system according to claim 13, wherein parts of the at least one turn of the second induction detector can be placed in a first relative position and in at least one second relative position, wherein, in the first relative position, the parts can assume such a predetermined position with respect to a part of a rail that that part of a rail can operatively be included in a predetermined magnetic field, and wherein, in the at least one second relative position, direct replacement of the at least one turn with the parts again in the first relative position is possible at a part of another rail.

33-39. (canceled)

40. Method for measuring the magnetizability of at least a part of a rail, for instance a rail for guiding means of transport, in a direction transverse to a longitudinal direction of at least said part of the rail, comprising the steps:
positioning a substantially saddle-shaped transmitter coil partly around the rail so as to extend substantially in the longitudinal direction of the rail on either side of the rail,
using said transmitter coil generating at least one predetermined changing magnetic field, wherein a length of the transmitter coil, measured in the longitudinal direction, is at least four times larger than a dimension of the substantially saddle-shaped coil measured in a direction substantially orthogonal to the longitudinal direction so as to provide that the magnetic field at or near the center of the transmitter coil is oriented substantially in the direction transverse to a longitudinal direction of at least said part of the rail,
arranging a magnetic induction detector adjacent to the rail at or near a center of the transmitter coil, and
measuring a magnetic induction oriented in the direction transverse to the longitudinal direction of the rail, using the magnetic induction detector.

41. Method according to claim 40, including using a calibration system according to claim 1.

42. Method according to claim 40, further including
generating at least one predetermined changing magnetic field in the longitudinal direction of the rail such that the respective part of a rail is located in that field; and
providing a magnetic induction detector for measuring a magnetic induction in the longitudinal direction of the rail at or near the location where the magnetic field in the longitudinal direction of the rail is generated,
measuring the magnetic induction in the longitudinal direction, and
determining a mechanical stress on the basis of the measured magnetic induction oriented in the direction transverse to the longitudinal direction of the rail and the magnetic induction in the longitudinal direction of the rail.

43. Method according to claim 42, including using a measurement system according to claim 13.
